(19) United States
(12) Patent Application Publication
(10) Pub. No.: US 2008/0067691 A1
(43) Pub. Date: Mar. 20, 2008

(54) Transistor Structure and Control Unit Comprising the Same

(75) Inventors: Chung-Yu Liang, Hsinchu (TW); Chun-Ching Wei, Hsinchu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU OPTRONICS CORP., Hsinchu (TW)

(21) Appl. No.: 11/849,622

(22) Filed: Sep. 4, 2007

(30) Foreign Application Priority Data
Sep. 14, 2006 (TW) 95134030

(51) Int. Cl. H01L 23/48

(52) U.S. Cl. 257/774; 257/E23.01

(57) ABSTRACT

A transistor structure and a control unit comprising the same transistor structure for use with the drive circuit of a liquid crystal display (LCD) are provided. The transistor structure comprises a first conductive layer, a second conductive layer, and a top gate to form a reinforced capacitance thereamong, thereby, significantly releasing the burden of the circuit layout due to the extra capacitance devices. That is, the capability of the capacitance can be improved without providing additional devices.

This application claims the benefits of Taiwan Patent Application No. 095134030, filed Sep. 14, 2006, the disclosures of which are incorporated by reference in their entirety.

### CROSS-REFERENCES TO RELATED APPLICATIONS

Not applicable.

### BACKGROUND OF THE INVENTION

1. Field of the Invention

The present invention relates to a transistor structure and a control unit with the same transistor structure. In particular, the invention relates to a transistor structure and a control unit comprising the transistor structure for use with the drive circuit of a liquid crystal display.

2. Descriptions of the Related Art

Liquid crystal displays (LCDs) are mainstream products in the display market. LCDs not only save power and emit low radiation, but they also are lightweight and portable. As one type of LCD, thin film transistor liquid crystal displays (TFT-LCDs) mainly comprise a display panel and a backlight module, wherein the display panel has a transistor array, a color filter substrate, and a liquid crystal filled therebetween. The operation of the previously mentioned components will result in an image display.

Generally speaking, many large-sized capacitors are additionally disposed to provide a voltage regulation effect, except for in cases where transistors are required in the external drive circuit of the LCD. However, these large-sized capacitors usually occupy a large area of the circuits. Consequently, the layout flexibility of other components and circuits are negatively impacted due to the space taken up by these large-sized capacitors in the circuit design. Furthermore, with the restriction of these large-sized capacitors, it is harder to adopt other circuit designs, such as increasing the ratio of the width over the length (W/L) of a channel of a transistor. Consequently, it is harder to further enhance the disposition and the performance of the drive circuit.

A conventional control unit of a liquid crystal display is shown in FIG. 1. For simplification, only a cross-sectional view illustrating a transistor structure 11 and the storage capacitance 12 of a control unit 10 is shown in FIG. 1. First, there comprises a control area 101 and a capacitance area 102 on a substrate 100. A first conductive layer 131, 132 is individually formed on both the control area 101 and the capacitance area 102. The dielectric layer 14 is covered thereon. Next, an amorphous-silicon layer 151, 152 is individually formed corresponding to the control area 101 and the capacitance area 102, wherein the amorphous-silicon layer 151 is used to provide flow channels for the carriers.

On the abovementioned structures and regions, an electrode layer 161, 162 is individually formed so the second conductive layer 171, 172 can be formed thereon. It is noted that the electrode layer 161 and the second conductive layer 171 allocated in the control area 101 are physically divided into two portions and separated by an interval. Finally, a planarization dielectric layer 18 (also known as a passivation layer) is formed on the aforesaid structure.

Apparently, as shown in FIG. 1, the storage capacitance 12 on the substrate 100 does occupy a certain transverse portion of the structure. With a top plane view, it is obvious that a large circuit area is taken up by the storage capacitance. This leaves restrictions on circuit disposition, which is unfavorable for product design and circuits minimization.

Given the above, a transistor structure and a control unit adapted to effectively minimize the area occupied by the capacitors in circuit layouts needs to be developed in this field.

### SUMMARY OF THE INVENTION

The primary objective of this invention is to provide a transistor structure and a control unit especially suitable for the drive circuit of a liquid crystal display (LCD). The transistor structure of the present invention is disposed with a top gate that overlays with the source electrode of the transistor structure. By enlarging the gate-source capacitance (CGS) of the transistor itself, a single-sided capacitance can be generated on the transistor structure in addition to the original capacitance. This can release the specification requirements of the conventional large-sized regulation capacitors by circuit layout reduction and can even replace the original capacitance structure, enabling greater flexibility in circuits design and disposition.

Another objective of this invention is to provide a transistor structure and a control unit. Because the regulation capacitors are completely or partially disposed on the transistor structure in the present invention, the area of the regulation capacitors can be minimized effectively and thus, the circuit design area occupied by the capacitance structure can be reduced significantly.

Yet a further objective of this invention is to provide a transistor structure and a control unit on which a top gate is disposed. Not only is the capacitor more effective, but the current flows of the transistor structure are also increased due to the top gate voltage enhancement above the current flowing channel. As a result, the performance of the transistor is enhanced.

To achieve the abovementioned objectives, the present invention provides a transistor structure successively comprising a first conductive layer, a dielectric layer, an amorphous-silicon layer, an electrode layer, a second conductive layer, a planarization dielectric layer, and a top gate. The specific arrangements are described as follows: (1) the dielectric layer overlays the first conductive layer; (2) the amorphous-silicon layer partially overlays the dielectric layer; (3) the electrode layer, including a first and a second electrodes with a formed interval for partially exposing the amorphous-silicon layer, is disposed on the amorphous-silicon layer; (4) the second conductive layer includes a first conductive portion partially disposed on the first electrode and a second conductive portion partially disposed on the second electrode; (5) the planarization dielectric layer at least overlays the second conductive layer and the amorphous-silicon layer which is partially exposed due to the interval; and (6) the top gate is disposed on the planarization dielectric layer in correspondence with the first conductive portion of the second conductive layer, and electrically connects with the first conductive layer. With the said aforementioned structure, the first conductive layer, the first conductive portion of the second conductive layer and the top gate are adapted to form a reinforced capacitance thereamong.

The present invention further provides a control unit comprising a substrate on which the aforementioned transistor structure and first capacitance structure are disposed on the substrate. The first capacitance structure is adjacent to the reinforced capacitance (the second capacitance structure) in the transistor structure. The control unit of the present invention minimizes the circuit design area occupied by the first capacitance structure.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic view illustrating a conventional control unit of a liquid crystal display;

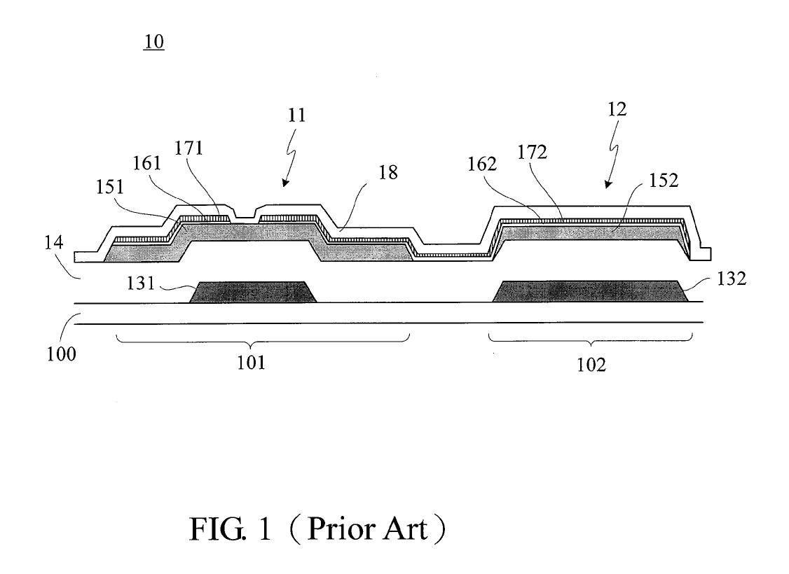

FIG. 2A is a cross-sectional view illustrating a preferred embodiment of the control unit of the present invention;

FIG. 2B is a top plane view of FIG. 2A;

FIG. 3 is a cross-sectional view illustrating another preferred embodiment of the control unit of the present invention;

FIG. 4 is a cross-sectional view illustrating a preferred embodiment of the transistor structure of the present invention; and

FIG. 5 is a cross-sectional view illustrating another preferred embodiment of the transistor structure of the present invention.

### DESCRIPTION OF THE PREFERRED EMBODIMENT

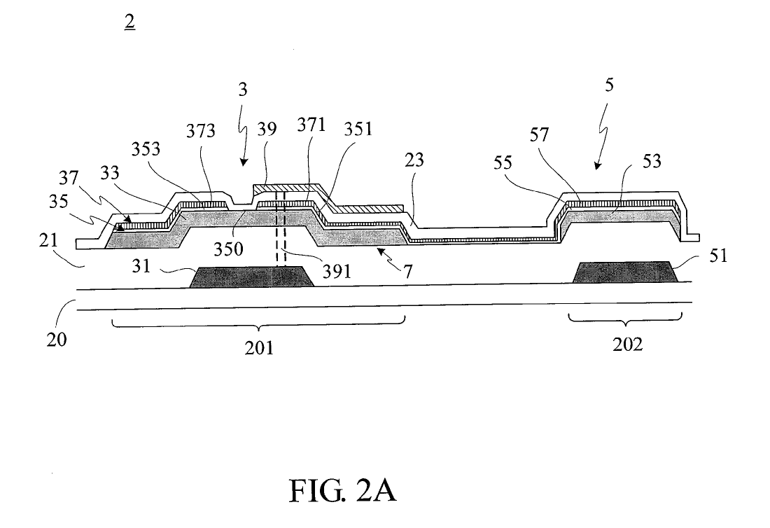

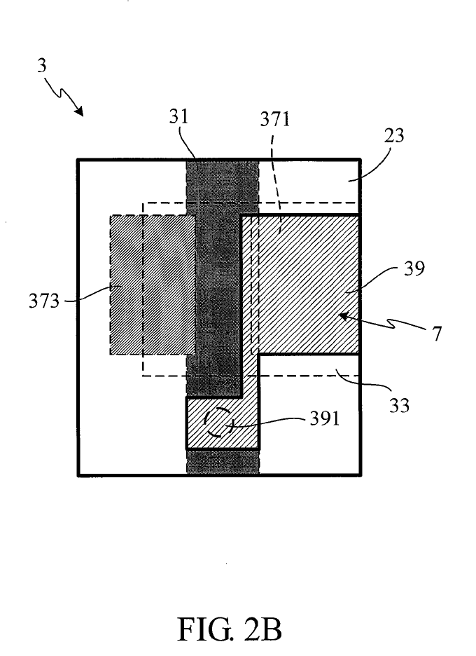

FIG. 2A is a cross-sectional view illustrating a preferred embodiment of a control unit 2 of the present invention. The control unit 2 comprises a transistor structure 3 and a first capacitance structure 5 disposed on the substrate 20. For simplification, the control area 201 and the capacitance area 202 are defined on the substrate 20. The aforesaid transistor structure 3 is located on the control area 201 while the first capacitance structure 5 is located on the capacitance area 202.

Specifically, the transistor structure 3 successively comprises a first conductive layer 31, a dielectric layer 21, an amorphous-silicon layer 33, an electrode layer 35, a second conductive layer 37, a planarization dielectric layer 23 and a top gate 39. The arrangement is described as follows: (1) the dielectric layer 21 overlays the first conductive layer 31; (2) the amorphous-silicon layer 33 partially overlays the dielectric layer 21; and (3) the electrode layer 35 is disposed on the amorphous-silicon layer 33, in which the electrode layer 35 includes a first electrode 351 and a second electrode 353 between which an interval 350 is formed for partially exposing the amorphous-silicon layer 33.

Furthermore, the second conductive layer 37 includes a first conductive portion 371 and a second conductive portion 373 that individually correspond to the first electrode 351 and the second electrode 351. In more detail, the first conductive portion 371 and the second conductive portion 373 are individually disposed for partially exposing the amorphous-silicon layer 33 from the interval 350.

The planarization dielectric layer 23 overlays the aforesaid structure. Specifically, the planarization dielectric layer 23 at least overlays the second conductive layer 37 and the amorphous-silicon layer 33 which is partially exposed from the interval 350. Finally, the top gate 39 is formed on the planarization dielectric layer 23 in correspondence with the first conductive portion 371 of the second conductive layer 37. In fact, the top gate 39 electrically connects with the first conductive layer 31 via a through hole 391. Referring to FIG. 2B, which is a top plane view illustrating a transistor structure 3, the voltage level between the top gate 39 and the first conductive layer 31 is equalized by disposing the through hole 391. Thus, the first conductive layer 31, the first conductive portion 371 of the second conductive layer 37, and the top gate 39 are adapted to form a second capacitance structure 7 thereamong.

For clarification, the first conductive layer 31 is a bottom gate. Preferably, the first conducive layer 31 and the second conductive layer 37 are made from metallic material for better conductance. The top gate 39 is an electrode, such as an indium-tin oxide (ITO) transparent electrode. In practice, the first electrode 351 is a source electrode, the second electrode 353 is a drain electrode, and the second capacitance structure 7 forms the gate-source capacitance (CGS).

Furthermore, the first capacitance structure 5 (i.e. the location of the original capacitance structure) is disposed adjacent to the second capacitance structure 7. The first capacitance structure 5 successively comprises a first conductive layer 51, a dielectric layer 21, an amorphous-silicon layer 53, an electrode layer 55, a second conductive layer 57, and a planarization dielectric layer 23, wherein the dielectric layer 21, the electrode layer 55, the second conductive layer 57 and the planarization dielectric layer 23 are extending from the corresponding components of the transistor structure 3, respectively.

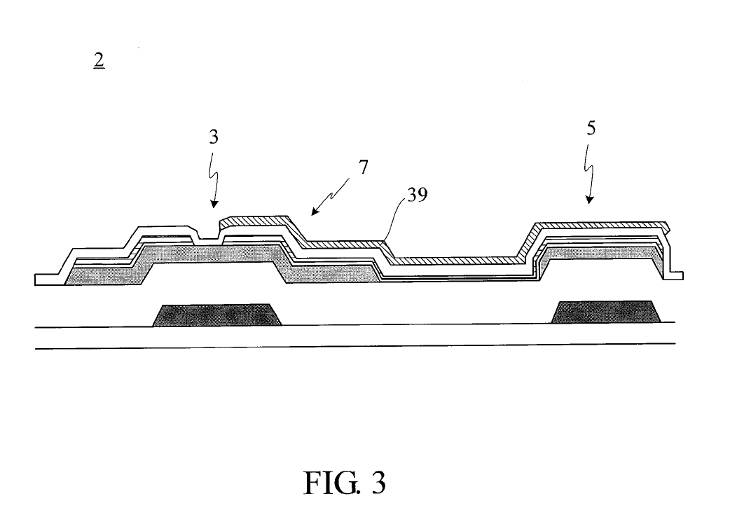

Another preferred embodiment of the present invention is shown in FIG. 3, wherein the top gate 39 extends from the second capacitance structure 7 onto the first capacitance structure 5. By the extension of the top gate 39, the capacitance of the drive circuit is enlarged and the effectiveness of voltage regulation of the control unit 2 is further enhanced.

In practice, the second capacitance structure 7 can be an extra reinforced capacitance in the control unit 2. It can be understood that the electric specifications of the original first capacitance structure 5 can be reduced because of the assistance of the second capacitance structure 7. Even though the first capacitance structure 5 can be eliminated, only the second capacitance structure 7 is enough to provide the capacitance requirement for the control unit 2.

Although the figures only illustrate cross-sectional views, in practice, it is further noted that there is a large overlap area among the top gate 39, the first conductive layer 31, and the first conductive portion 371 of the second conductive layer 37. The capacitance effect is significant enough for voltage regulation.

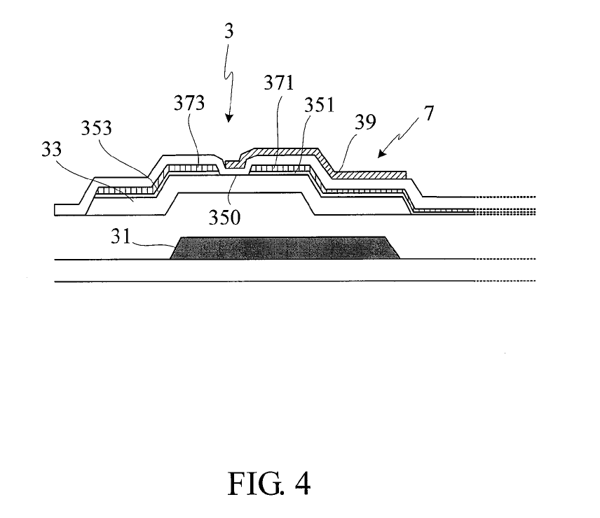

Another preferred embodiment is shown in FIG. 4. In this figure, only a detailed structure of the transistor structure 3 is shown. In this embodiment, the top gate 39 laterally extends to correspondingly and indirectly overlay the interval 350. By increasing the overlap area formed by the first conductive layer 31, the first conductive portion 371, and the upper gate 39, a greater amount of carrier electrons can be accumulated within the amorphous-silicon layer 33 corresponding to the interval 350. Consequently, the transistor structure 3 can induce greater currents.

FIG. 4 illustrates that the first conductive layer 31 may be further extended correspondingly along with the first electrode 351. With the disposed top gate 39, the corresponding area is increased, and thus, the second capacitance structure 7 can provide a greater capacitance regulation capability.

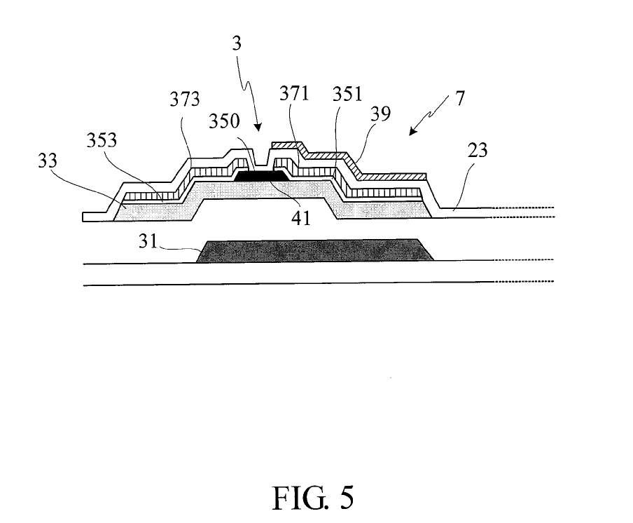

Yet another preferred embodiment is shown in FIG. 5. The control unit 2 further comprises an etching stop layer 41 disposed on the amorphous-silicon layer 33 in correspondence with the interval 350. The etching stop layer 41 is utilized in an etching process which is performed to form the interval 350 during the manufacturing process. However, if the etching time or the concentration of the etchant is not adequately controlled, the amorphous-silicon layer 33 may be damaged and thus, leads to a malfunction of the transistor structure 3. Therefore, the conventional amorphous-silicon layer 33 would be designed with a certain thickness. With the etching stop layer 41 in this embodiment, the etching depth resulting from the etching process could be precisely controlled. The etching stop layer 41 can protect the amorphous-silicon layer 33 from improper etching. That is, the etching depth would be limited by the etching stop layer 41, ensuring that no damage occurs to the amorphous-silicon layer 33. Consequently, the amorphous-silicon layer 33 tends to be thinner. In practice, the thickness of the amorphous-silicon layer 33 can be significantly reduced approximately from 2000 Å to 500 Å. As shown in FIG. 5, the first electrode 351 and the second electrode 353 partially overlay the two opposite ends of the etching stop layer 41. Like the arrangements in the former embodiment, the extension of the first conductive layer 31 or the top gate 39 is also adapted to this embodiment, which is not further described here.

With the transistor structure and control unit disclosed in the present invention, an effective capacitance of the transistor structure is provided to reduce the size of the conventional regulation capacitors, or even substitute the large-sized regulation capacitors. Consequently, the occupied circuit area of the capacitance structure can be significantly minimized, whereby increasing the flexibility in the circuit design and disposition.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A transistor structure, comprising:
a first conductive layer;
a dielectric layer, overlaying the first conductive layer;
an amorphous-silicon layer, partially overlaying the dielectric layer;
an electrode layer, disposed on the amorphous-silicon layer, in which the electrode layer includes a first electrode and a second electrode between which an interval is formed for partially exposing the amorphous-silicon layer;
a second conductive layer, including a first conductive portion partially disposed on the first electrode, and a second conductive portion partially disposed on the second electrode;
a planarization dielectric layer, at least overlaying the second conductive layer and the amorphous-silicon layer partially exposing from the interval; and
an upper gate, disposed on the planarization dielectric layer in corresponding to the first conductive portion of the second conductive layer, and the upper gate electrically connecting with the first conductive layer;
whereby the first conductive layer, the first conductive portion of the second conductive layer, and the upper gate are adapted to form a reinforced capacitance thereamong.

2. The transistor structure as claimed in claim 1, wherein the transistor structure further comprises a through hole, for electrically connecting the upper gate and the first conductive layer.

3. The transistor structure as claimed in claim 1, wherein the upper gate laterally extends to substantially overlay the interval.

4. The transistor structure as claimed in claim 1, wherein the first conductive layer extends to a location corresponding to the first electrode.

5. The transistor structure as claimed in claim 1, further comprising an etching stop layer disposed on the amorphous-silicon layer in corresponding to the interval, wherein the first electrode and the second electrode partially overlay two opposite ends of the etching stop layer.

6. The transistor structure as claimed in claim 1, wherein the first conductive layer is a lower gate.

7. The transistor structure as claimed in claim 1, wherein the first conductive layer and the second conductive layer are made from metallic material.

8. The transistor structure as claimed in claim 1, wherein the upper gate is a transparent electrode.

9. The transistor structure as claimed in claim 1, wherein the first electrode is a source electrode and the second electrode is a drain electrode.

10. A control unit having a transistor, comprising a substrate, a transistor structure, and a first capacitance structure in which the transistor structure and the first capacitance structure are disposed on the substrate, wherein the transistor structure comprises:
a first conductive layer;
a dielectric layer, overlaying the first conductive layer;
an amorphous-silicon layer, partially overlaying the dielectric layer;
an electrode layer, disposed on the amorphous-silicon layer, in which the electrode layer includes a first electrode and a second electrode between which an interval is formed for partially exposing the amorphous-silicon layer;
a second conductive layer, including a first conductive portion partially disposed on the first electrode and a second conductive portion partially disposed on the second electrode;
a planarization dielectric layer, at least overlaying the second conductive layer and the amorphous-silicon layer partially exposing from the interval; and
an upper gate, disposed on the planarization dielectric layer in corresponding to the first conductive portion of the second conductive layer, the upper gate electrically connecting with the first conductive layer;
whereby the first conductive layer, the first conductive portion of the second conductive layer and the upper gate are adapted to form a second capacitance structure thereamong, and the first capacitance structure which is disposed adjacent to the second capacitance structure successively is adapted to contain a first conductive layer, a dielectric layer, an amorphous-silicon layer, an electrode layer, a second conductive layer, and a planarization dielectric layer wherein the dielectric layer, the electrode layer, the second conductive layer and the planarization dielectric layer of the first capacitance structure are extending from the dielectric layer, the electrode layer, the second conductive layer and the planarization dielectric layer of the transistor structure, respectively.

11. The control unit as claimed in claim 10, wherein the transistor structure further comprises a through hole, for electrically connecting the upper gate and the first conductive layer.

12. The control unit as claimed in claim 10, wherein the upper gate laterally extends to substantially overlay the interval.

13. The control unit as claimed in claim 10, wherein the upper gate extends to be disposed above the first capacitance structure.

14. The control unit as claimed in claim 10, wherein the first conductive layer extends to a location corresponding to the first electrode.

15. The control unit as claimed in claim 10, further comprising an etching stop layer disposed on the amorphous-silicon layer in corresponding to the interval, wherein the first electrode and the second electrode partially overlay two opposite ends of the etching stop layer.

16. The control unit as claimed in claim 10, wherein the first conductive layer is a lower gate.

17. The control unit as claimed in claim 10, wherein the first conductive layer and the second conductive layer are made from metallic material.

18. The control unit as claimed in claim 10, wherein the upper gate is a transparent electrode.

19. The control unit as claimed in claim 10, wherein the first electrode is a source electrode and the second electrode is a drain electrode.
